(19) United States
(12) Patent Application Publication
(10) Pub. No.: US 2015/0200229 A1
(43) Pub. Date: Jul. 16, 2015

(54) IMAGE SENSOR PIXEL WITH MULTILEVEL TRANSFER GATE

(71) Applicant: GVBB HOLDINGS S.A.R.L., Luxembourg (LU)

(72) Inventors: Jeroen ROTTE, Breda (NL); Peter CENTEN, Goirle (NL)

(73) Assignee: GVBB HOLDINGS S.A.R.L., Luxembourg (LU)

(21) Appl. No.: 14/157,454

(22) Filed: Jan. 16, 2014

(51) Int. Cl. H01L 27/148

(52) U.S. Cl. CPC H01L 27/14812

(57) ABSTRACT

An image sensor and a method for operating an image sensor are provided. In one aspect, the image sensor includes a pixel with multilevel transfer gate. The image sensor includes a pixel coupled to an output line. The pixel includes a photodiode configured to generate electrical charges in response to light. The pixel also includes a capacitive element for storing electrical charges for providing a value to the output line. A transfer gate is coupled between the photodiode and the capacitive element. The transfer gate is configured to activate to transfer the electrical charges between the photodiode and the capacitive element. The image sensor is configured to provide at least one control signal operating in a plurality of voltages to the transfer gate. The plurality of voltages is in addition to a voltage which deactivates the transfer gate.

### BACKGROUND

1. Field

The present disclosure relates generally to an image sensor, and more particularly, to an image sensor having a pixel with multilevel transfer gate.

2. Background

In recent years, CMOS image sensor (CIS) technology is gaining in popularity over charged coupled device (CCD). Starting with mobile devices, CIS offers lower cost because it can be manufactured using a standard CMOS process. CCD requires a specialized process. Moreover, CIS allows for more function integration, due to the use of the standard CMOS process. For example, each CIS pixel includes a buffer, which may improve the performance of the CIS over the CCD. Recently, CIS is starting to be adopted for broadcasting systems.

CIS is an example of active matrix sensor. In a pixel of a CIS, a photodiode generates electrical charges. An example of the photodiode is a p-n junction diode. In one implementation, the photodiode generates hole-electron pairs. The electrons are accumulated or integrated in the p-diffusion region of the photodiode. After an integration period, the charges accumulated are transferred to a floating diffusion via a transfer gate. In other words, the floating diffusion (C) generates a voltage (dV) from the accumulated charges (dQ) or dV=dQ/C and is coupled to the output line. In one aspect, the floating diffusion functions as a storage element. The voltage on the floating diffusion is coupled to an output line via a buffer.

In another aspect, the CIS includes an array (rows and columns) of the described pixels. In one implementation, the output lines may function as the column lines of the array. The pixels are coupled to the output lines by the rows sequentially. An output circuit coupled to the output lines performs further determining functions. For example, the output circuit may include an integrator that integrates the voltage of an output line, an operational amplifier, or an analog-to-digital converter that convert the integrated voltage to a digital value.

In another aspect, the CIS may include electronic shutter function. In one example, the shutter resets the charge integration in a group of pixels. An example is a global shutter which resets all the pixels in the CIS. The examples given are based on using the electrons to generate the wanted signal. The holes are drained off in this case. The mechanism works equally well for holes except that voltage changes reverses. Now the holes generate the wanted signal and the electrons are drained off.

### SUMMARY

In an aspect of the disclosure, an image sensor and a method for operating an image sensor are provided. In one aspect, the image sensor includes a pixel with multilevel transfer gate. The image sensor includes a pixel coupled to an output line. The pixel includes a photodiode configured to generate electrical charges in response to light. The pixel also includes a capacitive element for storing electrical charges for providing a value to the output line. A transfer gate is coupled between the photodiode and the capacitive element. The transfer gate is configured to activate to transfer the electrical charges between the photodiode and the capacitive element. The image sensor is configured to provide at least one control signal operating in a plurality of voltages to the transfer gate. The plurality of voltages is in addition to a voltage which deactivates the transfer gate.

In another aspect, the image sensor further includes a control circuit for providing the at least one control signal to the transfer gate. The control circuit includes a multiplexer configured to selectively couple at least one of the plurality of voltages onto the control signal.

In another aspect, the transfer gate includes a metal-oxide-semiconductor (MOS) transistor, and a gate of the MOS transistor is coupled to the control signal.

In another aspect, the plurality of voltages includes a voltage which activates the transfer gate to transfer the electrical charges between the photodiode and the capacitive element.

In another aspect, the plurality of voltages further includes a second voltage between the voltage which activates the transfer gate and the voltage which deactivates the transfer gate. In yet another aspect, the second voltage is provided prior to providing the voltage which activates the transfer gate to the at least one control signal of the transfer gate in a cycle.

In another aspect, the plurality of voltages further includes a third voltage between the voltage which activates the transfer gate and voltage which deactivates the transfer gate. In yet another aspect, the third voltage is provided after providing the voltage which activates the transfer gate to the at least one control signal of the transfer gate in the cycle.

In another aspect, the second voltage is provided after providing the voltage which activates the transfer gate to the at least one control signal of the transfer gate in a cycle.

It is understood that other aspects of apparatus and methods will become readily apparent to those skilled in the art from the following detailed description, wherein various aspects of apparatus and methods are shown and described by way of illustration. As will be realized, these aspects may be implemented in other and different forms and its several details are capable of modification in various other respects. Accordingly, the drawings and detailed description are to be regarded as illustrative in nature and not as restrictive.

### BRIEF DESCRIPTION OF THE DRAWINGS

FIG. 1 is a diagram illustrating an image sensor pixel.

FIG. 2 is a diagram illustrating potential diagrams of a pixel.

FIG. 3(A) is a diagram illustrating an example of a pixel with multilevel transfer gate.

FIG. 3(B) is a diagram illustrating another example of a pixel with multilevel transfer gate.

FIG. 4 is a diagram illustrating an array of pixels.

FIG. 5 is a diagram illustrating the timing diagram for an operation of the array of pixels.

FIG. 6 is a diagram illustrating voltages for operations of a pixel with multilevel transfer gate.

FIG. 7 is potential diagrams of a pixel with multilevel transfer gate.

FIG. 8 is a diagram of a flowchart of the operations of a pixel with multilevel transfer gate.

FIG. 9 is a chart showing an effect a pixel with multilevel transfer gate.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Several aspects of the image sensor will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

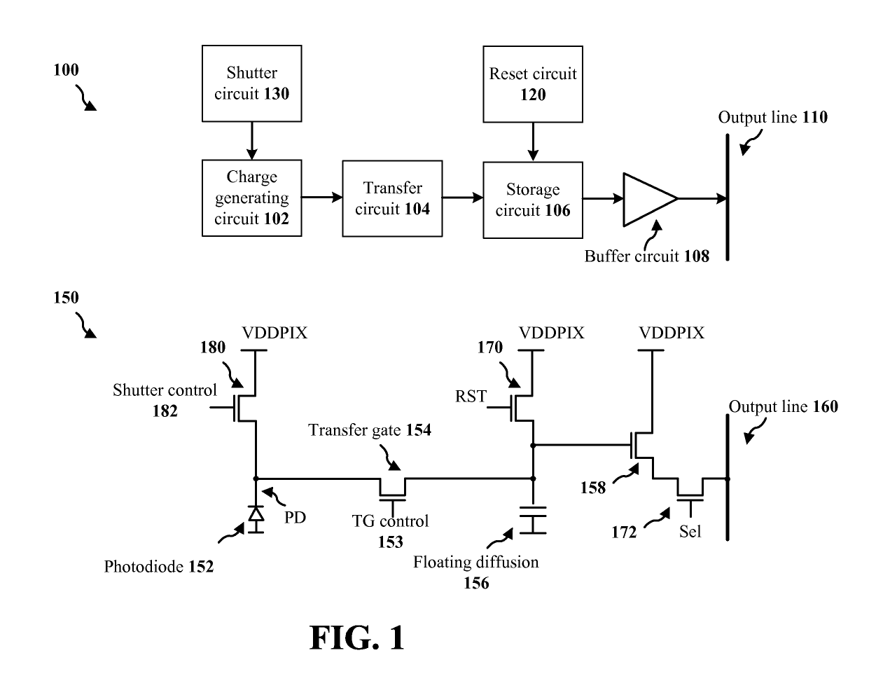

FIG. 1 is a diagram illustrating an image sensor pixel 100. In one implementation, a charge generating circuit 102 may generate electrical charges (e.g., electrons) in response to light. The electrical charges may be accumulated or integrated in an integration period. As an example, for a 50 Hz image sensor, the integration period may be 20 ms. After the integration period, the charges accumulated may be transferred to a storage circuit 106 via a transfer circuit 104. In one aspect, the accumulated charges at the charge generating circuit 102 may be transferred to the storage circuit 106. The charge is converted into a voltage in storage circuit 106. The voltage on the storage circuit 106 may be coupled to an output line 110 via a buffer circuit 108. The reset circuit 120 may reset the voltage on the storage circuit 106.

In one implementation, a shutter circuit 130 may perform the shutter function by, e.g., controlling the integration time of the pixel 100. In one example, the integration time may be controlled by the shutter circuit 130 resetting the charge generating circuit 102 according to a predetermined timing. Such predetermined timing may correspond to the integration time. In one example, the shutter circuit 130 may be part of a global shutter function. I.e., all pixels in an array may be controlled by the same shutter timing.

Pixel 150 is another view of an image sensor pixel. In one implementation, a photodiode 152 may generate electrical charges (e.g., electrons) in response to light. In one example, the photodiode 152 may be a pinned photodiode completely depleted and pinned to a voltage potential (known as Vₚᵢₙ) before any charges are generated. The electrical charges may be accumulated or integrated at node PD (which may be, e.g., a node in the photodiode 152) in an integration period. After the integration period, the charges accumulated at node PD may be transferred to a floating diffusion 156 via a transfer gate 154. In one aspect, the accumulated charges at node PD may be coupled to the floating diffusion 156 generating a voltage.

In one aspect, the floating diffusion 156 may function as a storage element for storing the generated charges for outputting a value to the output line 110. In one example where the accumulated charges are electrons, the floating diffusion 156 may be an N-type diffusion that is floating (i.e., not directly tied to any voltage potential). The transfer gate 154 may be a metal-oxide-semiconductor field-effect transistor (MOSFET) device controlled by a TG control signal 153. For example, the TG control signal 153 may be connected to the gate of the transfer gate 154.

The voltage on the floating diffusion 156 may be coupled to an output line 160 via a MOSFET 158 and a MOSFET 172. In example, the MOSFET 158 may be connected to voltage potential VDDPIX and may perform the buffer function on the voltage of the floating diffusion 156. The MOSFET 172 may selectively provide the output of the MOSFET 158 to the output line 160. In one aspect, the MOSFET 172 may be controlled by a SEL signal, and the SEL signal may correspond to a row activation of the pixel array. The reset circuit 170 may reset the voltage on the floating diffusion 156 by, e.g., supplying VDDPIX to the floating diffusion 156.

In one implementation, a MOSFET 180 may perform the shutter function by, e.g., controlling the integration time of the pixel 150. In one example, the integration time is controlled by the MOSFET 180 resetting the voltage on the node PD (which may be, e.g., a node in the photodiode 152) according to predetermined timing. Such predetermined timing may correspond to the integration time. In one example, the MOSFET 180 may be part of a global shutter function. I.e., all pixels in an array may be controlled by the same shutter timing. In one example, the resetting may include the MOSFET 180 functioning as a supply circuit supplying, in a first charge holding capacity, a reset voltage to the node PD. The supply voltages to the drain of MOSFET 180 and/or 170 may be different from MOSFET 158. A control signal, shutter control 182, may be supplied to the gate of the MOSFET 180 to control the drain capacity of the MOSFET 180. In one aspect, the control signal (shutter control 182) may operate at a high voltage level to enable the MOSFET 180 to drain the electrons from the photodiode 152, at a first capacity. In another aspect, the control signal (shutter control 182) may be at a low voltage level, to turn the MOSFET 180 off and not draining any electrons from the photodiode 152.

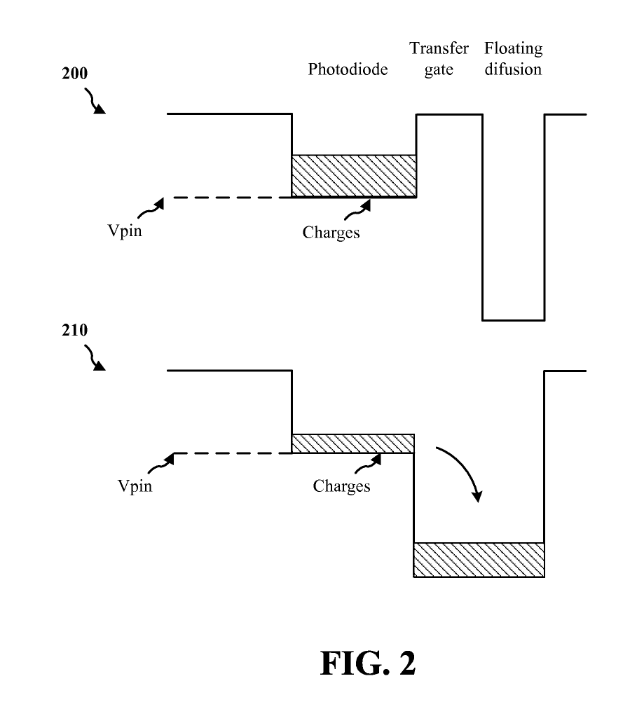

FIG. 2 is a diagram illustrating potential diagram of the pixel. The potential diagram 200 illustrates a state of charge integration before the transfer gate 154 is activated. As illustrated, the electrons are accumulated in the photodiode 152. The potential diagram 210 illustrates a state of charge transfer to the floating diffusion 156. In one aspect, the transfer gate 154 control signal (TG control signal) may go high to activate the transfer gate 154. The electrons accumulated in the photodiode 152 may flow to the floating diffusion 156 when the transfer gate 154 is activated.

Acquisition of an image takes for 20 ms for 50 Hz systems. During these 20 ms, dark current may be generated within the pixel. In one aspect, dark current is the small electric current that flows through photosensitive devices such as a photodiode or CCD, even when no photons are entering the device. The dark current may be due to the random generation of electrons and holes within the depletion region of the device that are then swept by the high electric field. To minimize dark current, the TG control signal 153 may be switched low.

In one aspect, charges, such as holes, may accumulate in the transfer gate channel before the transfer (i.e., before the transfer gate 154 is turned on for the transfer). The TG control signal 153 going low or even negative may minimize dark current, but may lead to hole accumulation in the transfer gate channel.

In another aspect, during the opening of the transfer gate channel, the photo-generated charges recombine, and electrons may be in surface traps. When the transfer gate channel is closed, charge (such as the electrons) might be captured in potential pockets and traps. In one example, charges may remain under the transfer gate channel after the transfer gate 154 is turned off after the transfer. The charges remaining in the transfer channel may be read out in a subsequent transfer. However, when applying exposure time control such as the global shutter, these charges may be reset and lost. A loss of picture quality (e.g., in darker areas) may result. In one aspect, the relationship of an image and a generated, corresponding photo-current of a pixel may become non-linear.

In one aspect of a pixel with multilevel transfer gate, the multilevel transfer gate may receive a control signal at a voltage prior that generate charges in the transfer gate channel, before the transfer. The control signal voltage may be slightly above the ground level and may have an effect of generating electrons in the transfer gate channel, causing the trapped holes to recombine with the electrons before the transfer. In another aspect of a pixel with multilevel transfer gate, the multilevel transfer gate may receive the control signal at a different voltage after the transfer. The different control signal voltage may be lower than the activation voltage of the transfer gate and may have an effect of allowing a more complete transfer of the charges (e.g., less charges trapped remain in the transfer gate channel after the transfer).

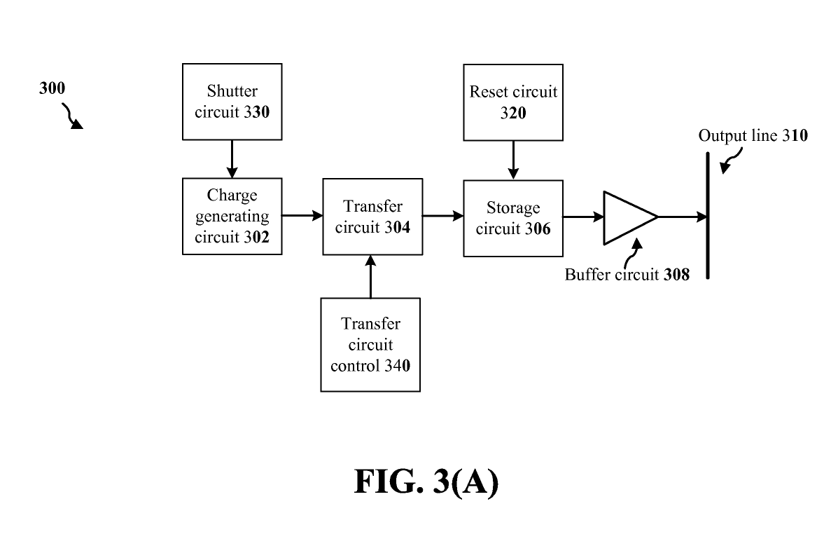

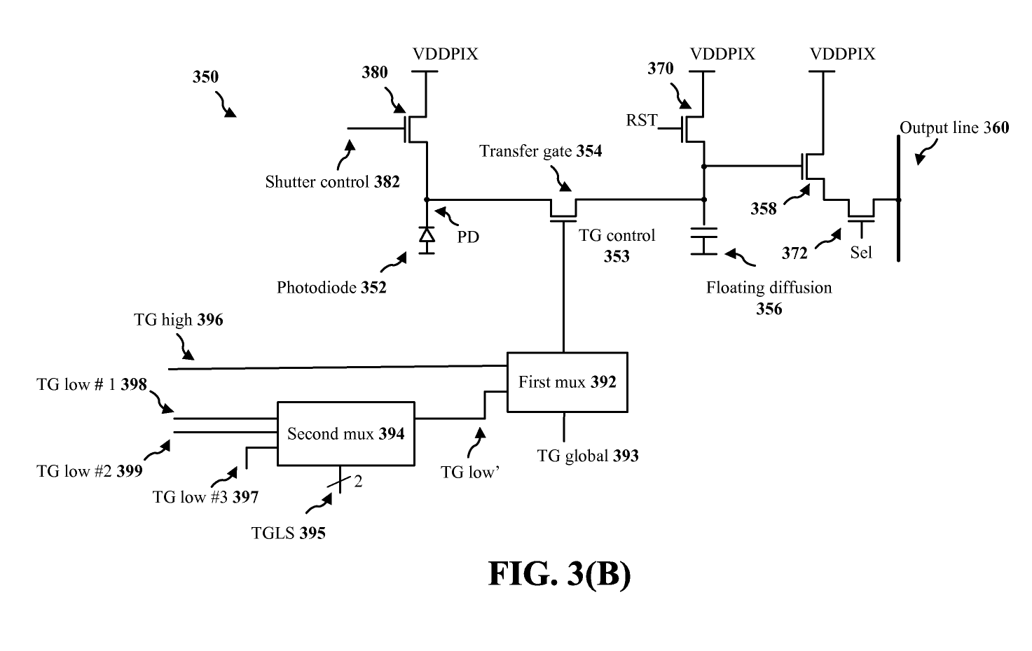

FIG. 3A is a diagram of an example of a pixel having a multilevel transfer gate. In addition to the features described with the pixel of FIG. 2 (100, 150), the pixel 300 includes a transfer circuit control circuit 340 providing at least one control signal to the transfer circuit 304. In one aspect, the transfer circuit 304 is multilevel. For example, a plurality of voltages (besides the ground level) may be provided to the at least one control signal.

FIG. 3B illustrates a pixel 350 having a multilevel transfer gate. In addition to the features of pixel 150, pixel 350 includes a multilevel transfer gate 354. The multilevel transfer gate 354 may be a metal-oxide-semiconductor field-effect transistor (MOSFET) device controlled by a TG control signal 353. For example, the TG control signal 353 may be connected to the gate of the transfer gate 354.

In one aspect, the control circuit includes multiplexers 392 and 394 and provides a plurality of voltage to the TG control signal 353 controlling the transfer gate 354. In one example, the plurality of voltages of the TG control signal 353 may include a TG high voltage level (at 396) which activates the transfer gate 354 for transferring charges between the photodiode 352 and the floating diffusion 356. In one example, TG high may be between 3.3-4.5 volt.

In one example, the second multiplexer 394 selects from a voltage level TG low #1 (at 398), a voltage level TG low #2 (at 399), and a voltage level TG low #2 (at 399), and a voltage level TG low #3 (at 397), and output the selected voltage to TG low′. In one example, the voltage level TG low #3 may be a small positive or a ground level. In another example, the voltage level TG low #3 may be a level below ground or a negative voltage for minimizing the dark current. In one example, TG low #3 may be between −0.5-1.0 volt. The control signal TGLS controls the selection. In one example, TGLS includes a plurality of signals for selecting from the three inputs (in this example, TGLS may include two signals). As is known in the art, when the ground level or below (e.g., TG low #3) is provided to the TG control signal 353, the transfer gate 354 may be shut off.

In another example, the first multiplexer 392 selects from TG high (at 396) and the TG low′, and provides the selected voltage to the TG control signal 353. Thus, in one example, a plurality of voltages including TG high, TG low #1, TG low #2, and TG low #3 may be provided to the TG control signal 353. Selectively providing additional voltages to the TG control signal 353 is possible.

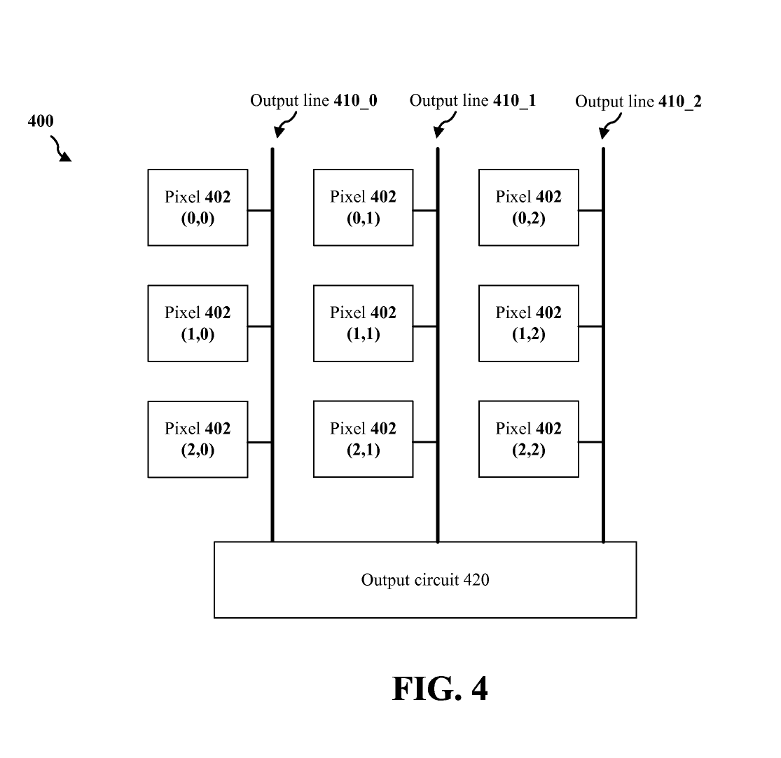

FIG. 4 is a diagram illustrating an array of three rows by three columns of pixels 402. In one aspect, each row may be activated in turn to couple the voltage of the photodiode 352 (e.g., as described above, via transfer gate 354, a floating diffusion 356, and a MOSFET 358 (buffer)) onto the output or column lines 410. For example, a row of pixels 402 (0,0), 402 (0,1), and 402 (0, 2) may be activated first. The pixel 402 (0,0) may couple the voltage on the photodiode 352 onto the output line 410_0. The pixel 402 (0,1) may couple the voltage on the photodiode 352 onto the output line 410_1. The pixel 402 (0,2) may couple the voltage on the photodiode 352 onto the output line 410_2. In one implementation, the values on the output lines 410_0, 410_1, and 410_2 may be read out sequentially by the output circuit 420. For example, the output circuit 420 may include an OA amplifying the values of the output lines 410_0, 410_1, and 410_2. In a subsequent cycle, the row of pixels 402 (1,0), 402 (1,1), and 402 (1, 2) may be activated next, and so forth.

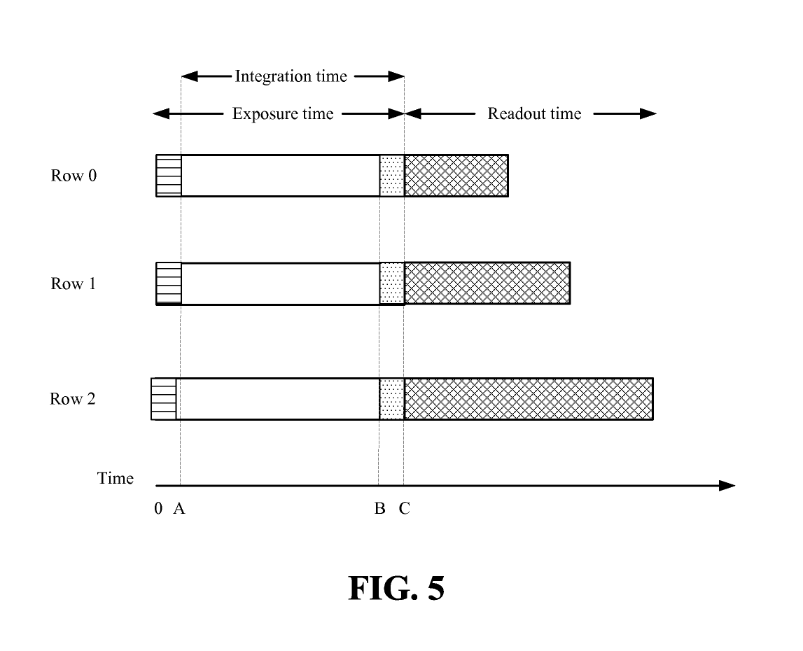

FIG. 5 is a diagram illustrating the timing diagram for an operation of a pixel. At time 0-A, the photodiode is reset. For example, the MOSFET 380 (the shutter or voltage supply circuit) may supply a reset voltage to the photodiode 352, which pins the voltage of the photodiode 352 at a reset voltage Vₚᵢₙ. At time A-C, the integration time, the electrons may accumulate or integrate at node PD. At time B-C, the transfer gate 354 may activate to couple the charges/voltage at node PD onto the floating diffusion 356. The time after time C may constitute data readout time. In a case that the rows are readout sequentially, the readout time may differ for the rows, as illustrated in the figure. In one aspect, the integration operation and the readout operation may be pipelined. For example, the next integration time for a row may start at time C, when the data of the previous integration is being read out.

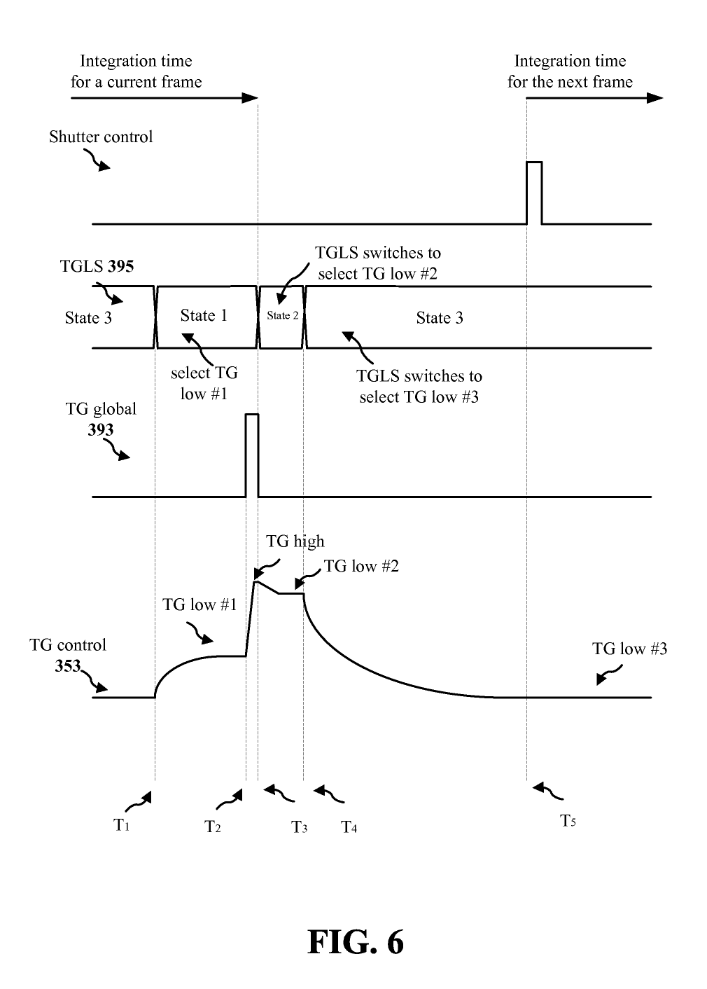

FIG. 6 is a diagram illustrating voltages for an operation of the pixel with multilevel transfer gate (350). In the integration time of a cycle and prior to T₁, TGLS 395 is in state 3, which selects and provides TG low #3 (the ground level or below) the TG low.′ TG global 393 is also low, selecting and proving TG low #3 (the ground level or below) at the TG low′ to the TG control 353. Therefore, the transfer gate 354 is shut off.

At T₁, TGLS 395 goes to state 1, which selects TG low #1 (398). As shown in FIG. 6, the voltage level at the TG control 353 slowly rises to the TG low #1 level in the period between T₁ and T₂. In one example, the period between T₁ and T₂ may be 50 μs. In one example, the voltage level TG low #1 is an intermediate level between TG high and the TG low #3 (e.g., the voltage which deactivates the transfer gate 354). In one example, TG low #1 may be between −0.5-3.0 volt. The TG low #1 may be slightly above the ground level and may have an effect of generating electrons in the channel of the transfer gate 354, causing the trapped holes in the channel of the transfer gate 354 to recombine with the electrons before the transfer. In this period, the dark current may rise. However, in a case that the period is limited, a surprising result is that the dark current increase has negligible effect on the performance of the image sensor. In one example, the period of 50 μs in the 20 ms integration achieves the desired result of negligible dark current increase.

At T₂, the TG global 393 goes high, and voltage level TG high is provided to the TG control 353. As a result, transfer gate 354 is activated (the charge transfer period starts), and charges/voltage on the node PD is transferred to the floating diffusion 356. The period between T₂ and T₃ is the charge transfer period.

At T₃, the TG global 393 goes low (the charge transfer period ends), and the TGLS 395 switches to state 2, which selects TG low #2 (399). Accordingly, the voltage level TG low #2 is provided to the TG control 353. In one example, the voltage level TG low #2 is an intermediate level between TG high and the TG low #3 (e.g., the voltage which deactivates the transfer gate 354). In another example, the voltage level TG low #2 is between TG high and photodiode pin voltage Vₚᵢₙ. In one example, TG low #2 may be between −0.5-3.0 volt. Accordingly, the TG control 353 does not drop to the ground level quickly, and the charge transfer period does not end abruptly. In one aspect, the voltage level TG low #2 on the TG control 353 may have an effect of allowing a more complete transfer of the charges into the floating diffusion 356 (e.g., less charges remain trapped in the transfer gate channel after the transfer).

At T₄, TGLS switches back to state 3 and selects the TG low #3 (the ground level to below) the TG low.′ TG global 393 is also low, selecting and proving the ground level or below at the TG low′ to the TG control 353. Therefore, the transfer gate 354 is gradually shut off.

At T₃, the current integration cycle ends, and at T₅ a new integration cycle may begin. The shutter control activates to resets, e.g., the photodiode 352. Effects flowing from the above described operations may include reduction of charges trapped in the transfer gate channel before and after the transfer of charges to the floating diffusion, and improved linearity between the image and the generated photo-current.

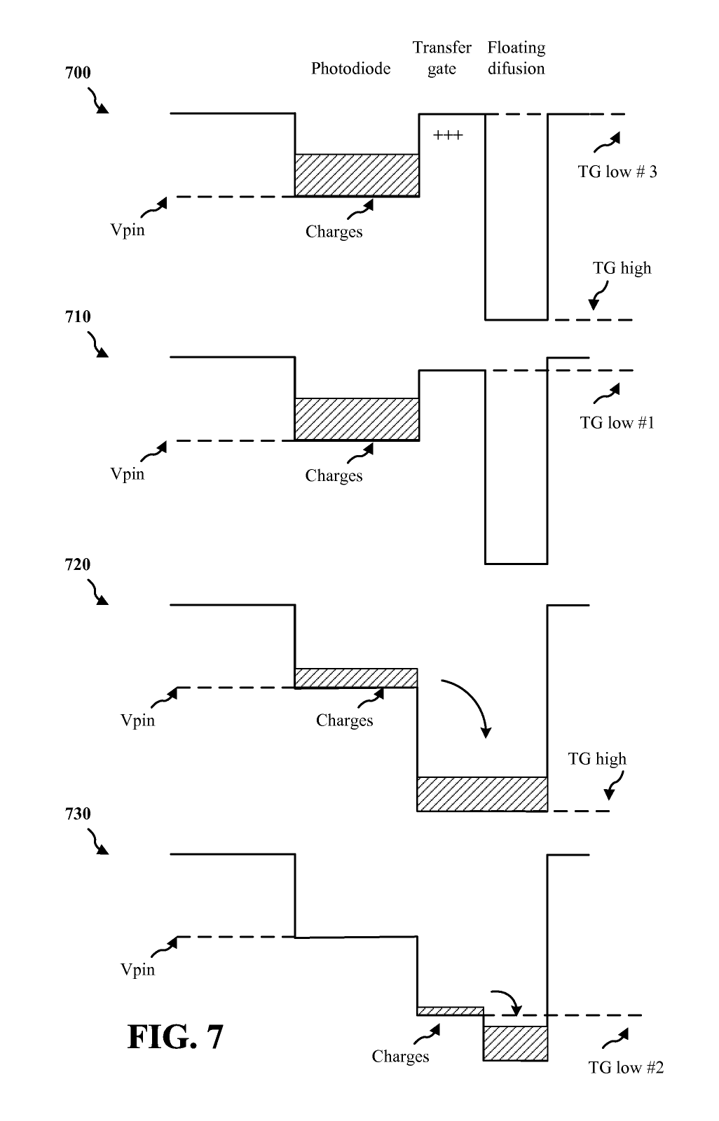

FIG. 7 includes potential diagrams of the operations of the pixel in accordance with FIG. 6. Diagram 700 is a potential diagram of a state before the transfer cycle (e.g., the period before T₁ in FIG. 6). The photodiode 352 accumulate charges in response to light. The TG control 353 is at the ground level, and the transfer gate 354 is in an off state. In this state, no charges accumulated in the photodiode 352 flow into the floating diffusion 356. Charges, such as holes, may accumulate in the channel of the transfer gate 354.

Diagram 710 is a potential diagram of a state before the transfer cycle and TG low #1 being provided to the TG control 353 (e.g., the period before T₁ and T₂ in FIG. 6). The holes accumulated in the channel of the transfer gate 354 may be removed due to the voltage level TG low #1 on the TG control 353.

Diagram 720 is a potential diagram of the charge transfer period (e.g., the period before T₂ and T₃ in FIG. 6). Voltage level TG high is provided to the TG control 353, and the transfer gate 354 is activated. The Charges accumulated in the photodiode 352 flow into the floating diffusion 356 via the activated transfer gate 354.

Diagram 730 is a potential diagram of a state after the charge transfer period and TG low #2 being provided to the TG control 353 (e.g., the period before T₃ and T₄ in FIG. 6). The charges trapped in the channel of the transfer gate 354 are allowed to continue to flow into the floating diffusion 356, as an effect of the voltage level TG low #2 on the TG control 353.

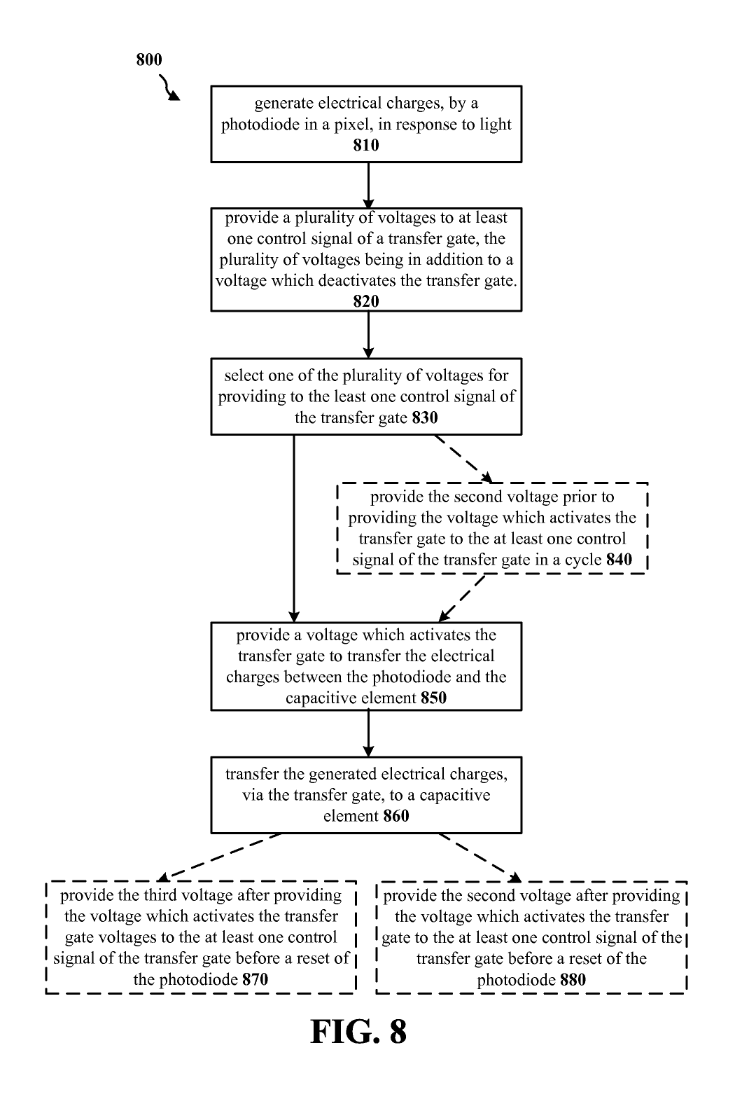

FIG. 8 is a diagram 800 of a flow chart of the operations of a pixel with multilevel transfer gate. At 810, a photodiode in a pixel generates electrical charges in response to light. At 820, a plurality of voltages is provided to at least one control signal of a transfer gate. The plurality of voltages is in addition to a voltage which deactivates the transfer gate. At 830, one of the plurality of voltages is selected for providing to the least one control signal of the transfer gate. At 840, in one aspect, the second voltage may be provided prior to providing the voltage which activates the transfer gate to the at least one control signal of the transfer gate in a cycle. At 850, a voltage which activates the transfer gate is provided to transfer the electrical charges between the photodiode and the capacitive element. At 860, the generated electrical charges are transferred, via the transfer gate, to a capacitive element. At 870, the third voltage may be provided after providing the voltage which activates the transfer gate voltages to the at least one control signal of the transfer gate before a reset of the photodiode.

At 880, in another aspect, the second voltage may be provided after providing the voltage which activates the transfer gate to the at least one control signal of the transfer gate before a reset of the photodiode. The disclosed operations of the flowchart may be in accordance of the operation described with FIGS. 6 and 7.

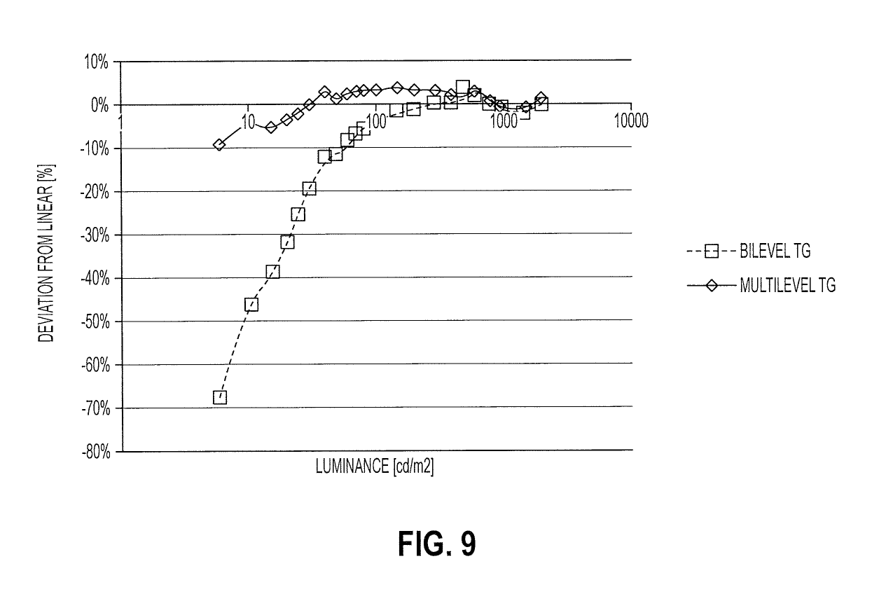

FIG. 9 is a chart showing an effect a pixel with multilevel transfer gate. The chart shows, for example, an improved linearity between the luminance of an image and the generated photo-current. The x-axis is the luminance of an image. The y-axis shows the deviation from linearity between the luminance of an image and the generated photo-current. For example, at low luminance, the chart shows that the pixel with multilevel transfer gate improves linearity from about (negative) 70% to about (negative) 10%.

It is understood that the specific order or hierarchy of steps in the processes/flow charts disclosed is an illustration of exemplary approaches. Based upon design preferences, it is understood that the specific order or hierarchy of steps in the processes/flow charts may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects.” Unless specifically stated otherwise, the term “some” refers to one or more. Combinations such as “at least one of A, B, or C,” “at least one of A, B, and C,” and “A, B, C, or any combination thereof” include any combination of A, B, and/or C, and may include multiples of A, multiples of B, or multiples of C. Specifically, combinations such as “at least one of A, B, or C,” “at least one of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. An image sensor, comprising:
a pixel coupled to an output line;
the pixel comprises:
a photodiode configured to generate electrical charges in response to light;
a capacitive element for storing electrical charges for providing a value to the output line;
a transfer gate coupled between the photodiode and the capacitive element, wherein the transfer gate is configured to activate to transfer the electrical charges between the photodiode and the capacitive element, and the image sensor is configured to provide at least one control signal operating in a plurality of voltages to the transfer gate, the plurality of voltages being in addition to a voltage which deactivates the transfer gate.

2. The image sensor of claim 1, further comprises a control circuit for providing the at least one control signal to the transfer gate.

3. The image sensor of claim 2, wherein the control circuit comprises a multiplexer configured to selectively couple at least one of the plurality of voltages onto the control signal.

4. The image sensor of claim 1, wherein transfer gate comprises a metal-oxide-semiconductor (MOS) transistor, and a gate of the MOS transistor is coupled to the control signal.

5. The image sensor of claim 1, wherein the plurality of voltages includes a voltage which activates the transfer gate to transfer the electrical charges between the photodiode and the capacitive element.

6. The image sensor of claim 5, wherein the plurality of voltages further includes a second voltage between the voltage which activates the transfer gate and the voltage that deactivates the transfer gate.

7. The image sensor of claim 6, wherein the second voltage is provided prior to providing the voltage which activates the transfer gate to the at least one control signal of the transfer gate in a cycle.

8. The image sensor of claim 7, wherein the plurality of voltages further includes a third voltage between the voltage which activates the transfer gate and the voltage that deactivates the transfer gate.

9. The image sensor of claim 8, wherein the third voltage is provided after providing the voltage which activates the transfer gate to the at least one control signal of the transfer gate, before a reset of the photodiode.

10. The image sensor of claim 6, wherein the second voltage is provided after providing the voltage which activates the transfer gate to the at least one control signal of the transfer gate, before a reset of the photodiode.

11. A method for an image sensor, comprising:
generating electrical charges, by a photodiode in a pixel, in response to light;
transferring the generated electrical charges, via a transfer gate, to a capacitive element;
providing a plurality of voltages to at least one control signal of the transfer gate, wherein the plurality of voltages being in addition to a voltage which deactivates the transfer gate.

12. The method of claim 11, further comprises selecting one of the plurality of voltages for providing to the least one control signal of the transfer gate.

13. The method of claim 11, wherein transfer gate comprises a metal-oxide-semiconductor (MOS) transistor, and a gate of the MOS transistor is coupled to the control signal.

14. The method of claim 11, wherein the plurality of voltages includes a voltage which activates the transfer gate to transfer the electrical charges between the photodiode and the capacitive element.

15. The method of claim 14, wherein the plurality of voltages further includes a second voltage between the voltage which activates the transfer gate and the voltage that deactivates the transfer gate.

16. The method of claim 15, wherein the second voltage is provided prior to providing the voltage which activates the transfer gate to the at least one control signal of the transfer gate in a cycle.

17. The method of claim 16, wherein the plurality of voltages further includes a third voltage between the voltage which activates the transfer gate and the voltage that deactivates the transfer gate.

18. The method of claim 17, wherein the third voltage is provided after providing the voltage which activates the transfer gate voltages to the at least one control signal of the transfer gate, before a reset of the photodiode.

19. The method of claim 15, wherein the second voltage is provided after providing the voltage which activates the transfer gate to the at least one control signal of the transfer gate, before a reset of the photodiode.

20. An image sensor, comprising:
a pixel coupled to an output line;
the pixel comprises:
charge generating means for generating electrical charges in response to light;
storage means for storing electrical charges for providing a value to the output line;
charge transferring means for transferring the generated electrical charges between the charge generating means and the storage means, wherein the charge transferring means is configured to activate to transfer the electrical charges between the charge generating means and the storage means, and the image sensor is configured to provide at least one control signal operating in a plurality of voltages to the charge transferring means, the plurality of voltages being in addition to a voltage which deactivates the charge transferring means.

21. The image sensor of claim 20, further comprises a control means for providing the at least one control signal to the charge transferring means.

22. The image sensor of claim 21, wherein the control means comprises a multiplexer configured to selectively couple at least one of the plurality of voltages onto the control signal.

23. The image sensor of claim 20, wherein the charge transferring means comprises a metal-oxide-semiconductor (MOS) transistor, and a gate of the MOS transistor is coupled to the control signal.

24. The image sensor of claim 20, wherein the plurality of voltages includes a voltage which activates the charge transferring means to transfer the electrical charges between the charge generating means and the storage means.

25. The image sensor of claim 24, wherein the plurality of voltages further includes a second voltage between the voltage which activates the charge transferring means and the voltage which deactivates the charge transferring means.

26. The image sensor of claim 25, wherein the second voltage is provided prior to providing the voltage which activates the charge transferring means to the at least one control signal of the charge transferring means in a cycle.

27. The image sensor of claim 26, wherein the plurality of voltages further includes a third voltage between the voltage which activates the charge transferring means and the voltage which deactivates the charge transferring means.

28. The image sensor of claim 27, wherein the third voltage is provided after providing the voltage which activates the charge transferring means to the at least one control signal of the charge transferring means, before a reset of the charge generating means.

29. The image sensor of claim 25, wherein the second voltage is provided after providing the voltage which activates the charge transferring means to the at least one control signal of the charge transferring means, before a reset of the charge generating means.
